(19) United States
(12) Patent Application Publication
(10) Pub. No.: US 2018/0143225 A1
(43) Pub. Date: May 24, 2018

(54) Detection Circuit for Power over Ethernet and Detection Current Generation Method Thereof

(71) Applicant: REALTEK SEMICONDUCTOR CORPORATION, Hsinchu (TW)

(72) Inventors: KAI-YIN LIU, HSINCHU CITY (TW); HUI-MIN HUANG, YUNLIN COUNTY (TW)

(21) Appl. No.: 15/714,946

(22) Filed: Sep. 25, 2017

(30) Foreign Application Priority Data
Nov. 22, 2016 (TW) 105138184

(51) Int. Cl. G01R 19/00; G05B 11/01; H04L 12/10

(52) U.S. Cl. CPC G01R 19/0092; H04L 12/10; G05B 11/01

(57) ABSTRACT

A detection circuit for power over Ethernet (PoE) and a detection current generation method thereof. The detection circuit for PoE is installed in power sourcing equipment (PSE), and generates a first detection current in a first detection mode to detect a power device (PD) of a first type and generates a second detection current in a second detection mode to detect a PD of a second type. The detection circuit of PoE includes a first current source group that has at least one first current source for generating part of the first detection current in the first detection mode, and a second current source group that has multiple second current sources for generating part of the first detection current in the first detection mode and generating the second detection current in the second detection mode. The first current source group does not generate current in the second detection mode.

### BACKGROUND OF THE INVENTION

### 1. Field of the Invention

The present invention relates to power over Ethernet (PoE), and, more particularly, to a detection circuit for PoE and its detection current generation method.

### 2. Description of Related Art

A power over Ethernet (PoE) system includes power sourcing equipment (PSE) and at least one power device (PD). The PDs are of various types. The PDs that were made before the Institute of Electrical and Electronics Engineers (IEEE) developed the PoE standard (e.g., IEEE 802.3af) and the ones that do not comply with the PoE standard are referred to as legacy PDs hereinafter. And the PDs that comply with the PoE standard are referred to as standard PDs hereinafter. While legacy PDs allow the use of larger capacitors, standard PDs only use smaller capacitors. PSE determines, if required, whether to detect and supply power to a legacy PD, and a relatively large electric current is needed to conduct the detection. Thus, it becomes an important issue in this technical field to provide a large electric current without increasing the circuit area of the detection circuit of the PSE.

### SUMMARY OF THE INVENTION

In view of the issues of the prior art, an object of this invention is to provide a detection circuit for power over Ethernet (PoE) and its detection current generation method so as to make an improvement to the prior art.

A detection circuit for PoE is disclosed. The detection circuit is disposed at power sourcing equipment (PSE) and operable to detect a type of a power device (PD) by generating a first detection current in a first detection mode and generating a second detection current in a second detection mode. The detection circuit comprises an output port, a first current source, a second current source, a third current source, and a control unit. The first current source generates a first current in the first detection mode. The second current source selectively generates a second current in the second detection mode. The third current source selectively generates a third current in the second detection mode. The control unit is coupled to the first current source, the second current source, and the third current source. In the first detection mode, the control unit controls the first current to be outputted at the output port such that the first detection current comprises the first current, and in the second detection mode, the control unit stops the first current from being outputted at the output port and controls at least one of the second current and the third current to be outputted at the output port such that the second detection current comprises at least one of the second current and the third current.

A detection circuit for PoE is also disclosed. The detection is disposed at PSE, and operable to generate a first detection current in a first detection mode to conduct detection of a PD of a first type and generate a second detection current in a second detection mode to conduct detection of a PD of a second type. The detection circuit comprises a first current source group and a second current source group. The first current source group comprises at least one first current source that generates part of the first detection current in the first detection mode. The second current source group comprises a plurality of second current sources that generate part of the first detection current in the first detection mode and generate the second detection current in the second detection mode. The first current source group does not generate electric current in the second detection mode.

A detection current generation method for PoE is also disclosed. The method is applied to PSE of PoE. The method generates a first detection current in a first detection mode to conduct detection of a PD of a first type and generates a second detection current in a second detection mode to conduct detection of a PD of a second type. The method comprises the steps of: using a first current source group to generate part of the first detection current in the first detection mode, the first current source group comprising at least one first current source; using a second current source group to generate part of the first detection current in the first detection mode, the second current source group comprising a plurality of second current sources; controlling the first current source group not to generate electric currents in the second detection mode; and using the second current source group to generate the second detection current in the second detection mode.

A detection circuit for PoE of this invention and its detection current generation method can provide large electric currents without increasing the circuit area. In comparison with the prior art, the detection circuit for PoE of the present invention can generate the required detection currents with a relatively small circuit area, and the power sourcing equipment (PSE) of PoE can use the detection currents generated to conduct detections of legacy power devices (PDs) and standard PDs.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 illustrates a power over Ethernet (PoE) system according to the present invention.

FIG. 2 illustrates a circuit diagram of part of the detection circuit inside the PSE 110.

FIG. 3 illustrates a flowchart of current calibration according to an embodiment of the present invention.

FIG. 4 illustrates a circuit diagram of part of the detection circuit inside the PSE 110 according to another embodiment of this invention.

FIG. 5 illustrates a flowchart of this method according to one embodiment.

### DETAILED DESCRIPTION OF THE EMBODIMENTS

The following description is written by referring to terms of this technical field. If any term is defined in this specification, such term should be explained accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

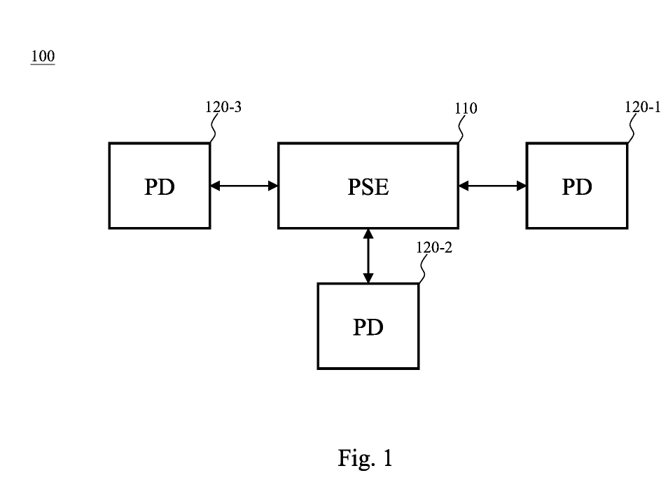

FIG. 1 illustrates a power over Ethernet (PoE) system according to the present invention. The PoE system 100 includes power sourcing equipment (PSE) 110 and three power devices (PDs) 120-1, 120-2 and 120-3. The three PDs are respectively connected to connection ports 1˜3 of the PSE 110 (not shown). It is assumed here that the PD 120-1 is a standard PD, and the PDs 120-2 and 120-3 are legacy PDs. To supply power to the PDs 120-1˜120-3 correctly, the PSE 110 detects the types of the PDs 120-1˜120-3 through connection ports 1˜3 before supplying power. Because the PDs include standard PDs and legacy PDs, the PSE 110 has a standard PD detection mode and a legacy PD detection mode. In the two detection modes, different detection currents are provided at the connection ports. More specifically, when detecting legacy PDs, the PSE 110 provides a first detection current at the connection ports one by one to separately conduct the detection of each PD; when detecting standard PDs, the PSE 110 can provide a second detection currents at all connection ports simultaneously to conduct the detections of all connected PDs at the same time. Because a legacy PD may include a large capacitor, the first detection current is typically greater than the second detection current. In one embodiment, in the detection process the first detection current is substantially a constant value with an order of, for instance, 100 μA˜2 mA. The second detection current, on the other hand, may change in the detection process, with an order of, for instance, 100 μA˜900 μA.

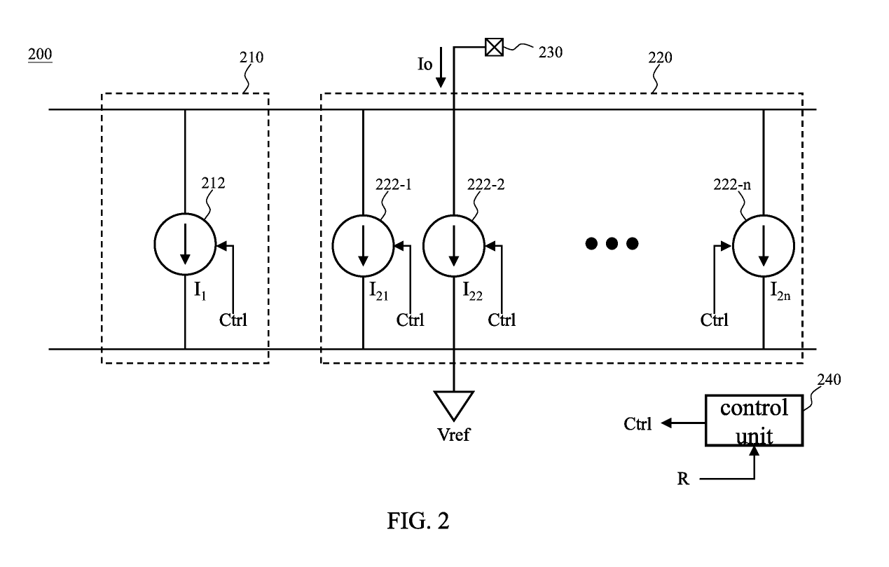

FIG. 2 illustrates a circuit diagram of part of the detection circuit inside the PSE 110. The detection circuit 200 includes a first current source group 210, a second current source group 220, an output port 230, and a control unit 240. The first current source group 210 includes at least one current source, and the second current source group 220 includes a plurality of current sources. Each current source is connected between the output port 230 and a reference voltage Vref (e.g., ground). In this embodiment, the first current source group 210 includes a current source 212, and the second current source group 220 includes current sources 222-1˜222-n, n being a positive integer. The first current source group 210 and the second current source group 220 are connected in parallel; that is, the current sources 212 and 222-1˜222-n are connected in parallel. The first current source group 210 is operable to provide part of the first detection current in the legacy PD detection mode, and the second current source group 220 is operable to provide the second detection current in the standard PD detection mode. A total current of the first current source group 210 is usually greater than a total current of the second current source group 220, i.e., I₁>I₂₁+I₂₂+ . . . +I₂ₙ. The current source 212 and the current sources 222-1˜222-n can be implemented by transistors (e.g., by making use of the fabrication of complementary metal-oxide-semiconductor (CMOS)), and generate the required electric currents based on the current mirror technology. Typically, the greater the electric current generated, the circuit area taken up by a current source becomes larger; thus, the current source 212 takes up the largest area among all the current sources. The entire circuit area of the detection circuit 200 can be effectively decreased if the area of the current source 212 is reduced. One of the methods is to increase a mismatch degree of current mirror of the current source 212 to reduce the circuit area (the lower the mismatch degree, the more accurate the electric current generated, with the requirement of a greater circuit area). This method, however, causes the electric current I₁ to be not able to reach a target value of the first detection current. Therefore, the present invention utilizes the following current compensation method as the circuit area of the current source 212 is reduced.

In the design of the first current source group 210, the electric current (or a sum of electric currents) thereof is intentionally designed to be lower than the target value of the first detection current, and the second current source group 220 is employed to compensate the insufficiency. For example, if the target value of the first detection current is 2 mA, and the second current source group 220 includes four current sources 222-1˜222-4, the electric current of the first current source group 210 (i.e., the electric current of the current source 212 in the embodiment of FIG. 2) can be designed as 2 mA-K, where K can be an intermediate value of combinations of the electric currents I₂₁˜I₂₄. More specifically, if the electric currents I₂₁˜I₂₄ are respectively 240 μA, 120 μA, 60 μA and 30 μA, the current sources 222-1˜222-4 can cooperatively provide 16 different current values at the output port 230, ranging from 0 μA (all current sources being inactive) to 450 μA (all current sources being active). Therefore, in this exemplary example, the intermediate value of combinations of the electric currents I₂₁˜I₂₄ can be 240 μA (i.e., only the electric current I₂₁ passing the output port 230) or 210 μA (the electric currents I₂₂, I₂₃, I₂₄ passing the output port 230), and K can thus be determined as 240 μA or 210 μA to facilitate the subsequent compensation operation. Since the mismatch degrees of the current sources 222-1˜222-4 are lower, the electric currents outputted by the second current source group 220 are relatively accurate. The current values of the multiple current sources of the current source group 220 can present a sequence of the powers of two; for instance, in the above exemplary example 121:122:123:124=8:4:2:1. This relationship serves only as an example, not a limitation, to the present invention.

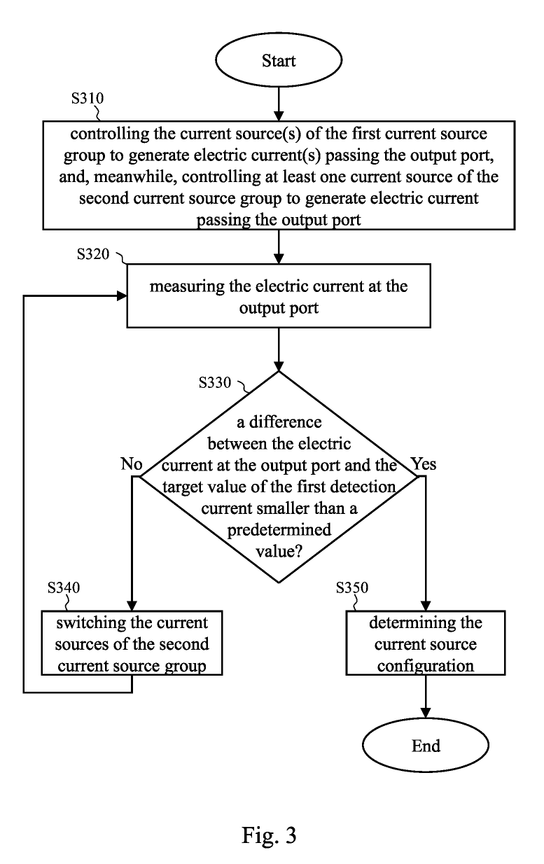

FIG. 3 illustrates a flowchart of current calibration according to an embodiment of the present invention. The method can be performed by the control unit 240, which, for example, may be a digital logic circuit that controls, by issuing control signals Ctrl, the current sources whether to output electric currents. Following the above example and assuming that K is determined as 240 μA, the electric current of the first current source group 210 is set as 2 mA-240 μA (i.e., the nominal value of the electric current of the first current source group 210 being 2 mA-240 μA). First, the current source(s) of the first current source group 210 (there being only the current source 212 in this exemplary embodiment) is/are controlled to generate electric current(s) passing the output port 230, and, meanwhile, at least one current source of the second current source group 220 is controlled to generate electric current passing the output port 230 (step S310). More specifically, in this step the current source(s) of the second current source group 220 corresponding to K (i.e., the current source 222-1 in this exemplary embodiment) is/are controlled to generate electric current(s) passing the output port 230. Ideally, a total current Io passing the output port 230 at the time is a sum of the nominal value of the electric current of the first current source group 210 (i.e., 2 mA-240 μA in this example) and the electric current of the current source 222-1 (i.e., 240 μA in this example), which should be 2 mA. Because there may be, however, errors due to the high mismatch degree of the current source 212 itself, the electric current Io at the output port 230 is measured to obtain a measurement result R (step S320). The control unit 240 then determines, based on the measurement result R, whether the electric current Io at the output port 230 is equal to the target value of the first detection current or whether a difference between the two is smaller than a predetermined value (step S330), and the control unit 240 further decides whether to adjust the configuration of the second current source group 220 according to the determination result.

When step S330 is negative, meaning that the difference between the electric current Io at the output port 230 and the target value of the first detection current is still greater than the predetermined value, the control unit 240 switches the current sources of the second current source group 220 (step S340) to compensate the electric current of the first current source group 210 with adjusted output current of the second current source group 220. After the switching process is complete, steps S320 and S330 are performed again. The above calibration process is repeated until step S330 becomes positive, and the current source configuration of the detection circuit 200 can thus be determined (step S350). For example, if I₁+I₂₁ is 2 mA-30 μA (i.e., I₁+I₂₁ being smaller than the target value of the first detection current by 30 μA), after the above calibration process, the current source configuration of the detection circuit 200 corresponding to the output electric current Io=2 mA is: the current sources 212, 222-1 and 222-4 being active, while the current sources 222-2 and 222-3 being inactive. In the subsequent detections of the legacy PDs, the control unit 240 causes the electric currents of the current sources 212, 222-1 and 222-4 to pass the output port 230, so that the output electric current Io can reach or approach the target value of the first detection current.

Note that in different embodiments where the electric current of the first current source group 210 is initially designed to be 2 mA-210 μA (i.e., K=210 μA), the current sources of the second current source group 220 corresponding to K=210 μA (i.e., the current sources 222-2, 222-3 and 222-4 in this example, as a total current of these three being 210 μA) are thus selected in step S310; as a result, the currents of the selected current sources are controlled to pass the output port 230. And it is assumed that I₁+I₂₂+I₂₃+I₂₄ is also 2 mA-30 μA (i.e., smaller than the target value of the first detection current by 30 μA), in step S340 the control unit 240 controls the output current of the second current source group 220 to increase (e.g., activating the current source 222-1 and deactivating the current sources 222-2˜222-4). The current source configuration is finally determined in step S350 as: the current sources 212 and 222-1 being active and the current sources 222-2˜222-4 being inactive.

How the detection circuit 200 of the PSE 110 generates the detection currents is illustrated in the following exemplary example where the PSE 110 conducts the detection of standard PDs before the detection of legacy PDs. The detection order, however, serves merely as an example, not a limitation, to the present invention. In the standard PD detection mode, the control unit 240 controls the first current source group 210 not to output electric currents and controls the second current source group 220 to generate the second detection current at the output port 230. The second detection current is outputted to the PDs through the connection ports. In one embodiment, to reduce the detection time, the detection circuit 200 can include as many second current source groups 220 as the number of connection ports of the PSE 110 (i.e., in this embodiment the detection circuit 200 includes three second current source groups 220 with two of which not shown) to output the second detection currents at the connection ports at the same time. In the detection process, the control unit 240 constantly switches the current sources 222-1˜222-n so that the second output current can have different current values (may have T values at most). The control unit 240 can learn whether the PD is a standard PD according to a voltage across the PD caused by the second detection current and/or according to the voltage changes over time. The detection accuracy can be improved when an offset of the voltage across the PD is learned by providing different second detection currents. For the embodiment of FIG. 1, after the standard PD detection mode is complete, the PSE 110 can learn that the PD 120-1 is a standard PD.

In the legacy PD detection mode, the control unit 240 controls the first current source group 210 to output electric currents, and controls the second current source group 220 to output electric currents according to the calibration result (i.e., the current source configuration determined in step S350); that is, the first detection current is made up of the electric currents outputted by the first current source group 210 and the second current source group 220. The first detection current is provided to the connection port through the output port 230, and is then outputted to the PD. In one embodiment, the PSE 110 outputs the first detection current through the connection ports one at a time; in other words, all connection ports share the first current source group 210. When the first detection current is outputted through connection port 2, part of the first detection current is provided by the first current source group 210, and part of the first detection current is provided, according to the previously obtained current source configuration, by the second current source group 220 corresponding to connection port 2. Similar mechanism can be applied to other connection ports and the detailed description thereof is thus omitted for brevity. Following the above example, since it is confirmed in the standard PD detection mode that the PD 120-1 is a standard PD, the PSE 110 can just output the first detection current through connection ports 2 and 3 one at a time in the legacy PD detection mode.

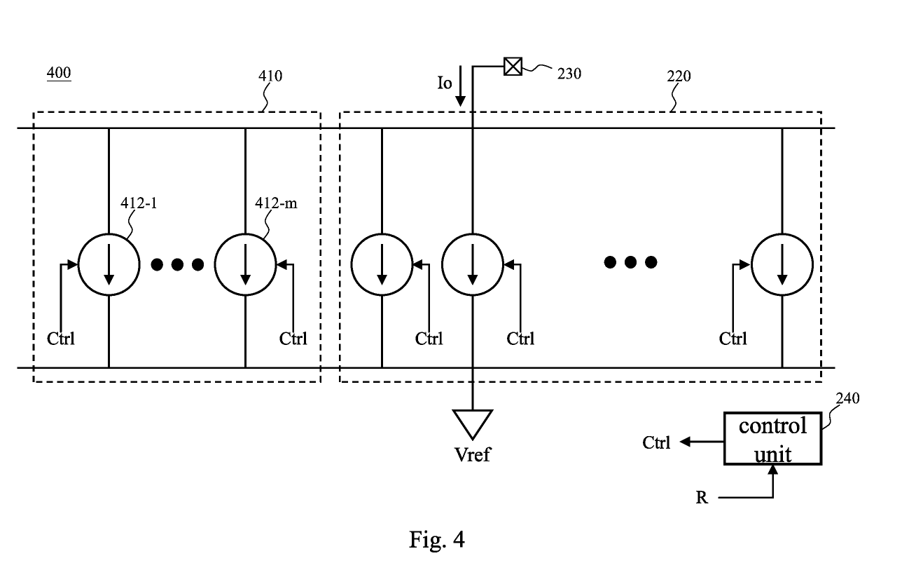

The first current source group may include more than one current source. FIG. 4 illustrates a circuit diagram of part of the detection circuit inside the PSE 110 according to another embodiment of this invention. The detection circuit 400 includes a first current source group 410, a second current source group 220, an output port 230 and a control unit 240. The first current source group 410 includes m current sources (412-1˜412-m) connected in parallel, m being a positive integer. In the calibration and the detection processes, all the current sources of the first current source group 410 are simultaneously active (i.e., outputting electric currents) or simultaneously inactive (i.e., not outputting electric currents). In other words, the current sources 412-1˜412-m of the first current source group 410 are equivalent to the sole current source 212 of the first current source group 210.

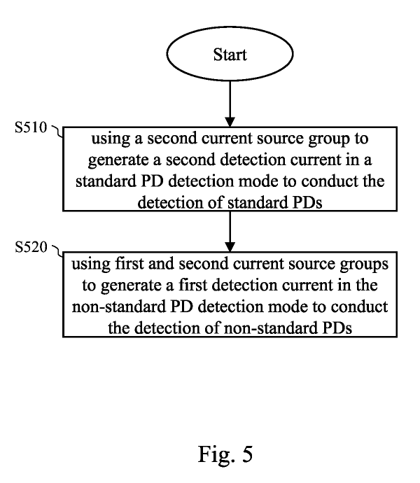

In addition to the aforementioned detection circuit, the present invention also correspondingly discloses a detection current generation method that is applied to PSE of PoE for the detections of standard PDs and legacy PDs. This method can be performed by the aforementioned detection circuit or the equivalent devices thereof. FIG. 5 illustrate a flowchart of this method according to one embodiment. The method includes the following steps:
step S510: using a second current source group to generate a second detection current in a standard PD detection mode to conduct the detection of standard PDs. As shown in the embodiments of FIGS. 2 and 4, the second current source group includes a plurality of current sources, and thus the second detection current is made up of the electric currents generated by the current sources. In this step, a first current source group is controlled not to generate electric currents, or the electric currents generated by the first current source group are prevented from being outputted to the output port of the detection circuit; and
step S520: using first and second current source groups to generate a first detection current in the legacy PD detection mode to conduct the detection of legacy PDs. In this detection mode, both the first current source group and the second current source group output electric currents. The first detection current is primarily provided by the first current source group, which may include one or more than one current source. The electric currents provided by the second current source group are used for compensation so that the first detection current can reach a target value.

Since people of ordinary skill in the art can appreciate the implementation detail and the modification thereto of the present method invention of FIGS. 3 and 5 through the disclosure of the device invention of FIGS. 1, 2, and 4, repeated and redundant description is thus omitted. Please note that there is no step sequence limitation for the method inventions as long as the execution of each step is applicable. Furthermore, the shape, size, and ratio of any element and the step sequence of any flow chart in the disclosed figures are exemplary for understanding, not for limiting the scope of this invention. The detection current generation method of this invention can be implemented by software and/or firmware in cooperation with hardware and can be performed by the detection circuit for PoE disclosed above or its equivalent devices.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A detection circuit for power over Ethernet (PoE), disposed at power sourcing equipment (PSE) and operable to detect a type of a power device (PD) by generating a first detection current in a first detection mode and generating a second detection current in a second detection mode, said detection circuit comprising:
an output port;
a first current source, for generating a first current in said first detection mode;
a second current source, for selectively generating a second current in said second detection mode;
a third current source, for selectively generating a third current in said second detection mode; and
a control unit, coupled to said first current source, said second current source, and said third current source, for, in said first detection mode, controlling said first current to be outputted at said output port such that said first detection current comprises said first current, and for, in said second detection mode, stopping said first current from being outputted at said output port and controlling at least one of said second current and said third current to be outputted at said output port such that said second detection current comprises at least one of said second current and said third current.

2. The detection circuit of claim 1, wherein said control unit further controls at least one of said second current and said third current to be outputted at said output port in said first detection mode such that said first detection current comprises said first current and at least one of said second current and said third current.

3. The detection circuit of claim 1, wherein said first detection current is used for detecting a PD of a first type, said second detection current is used for detecting a PD of a second type, a capacitor of said PD of said first type is greater than a capacitor of said PD of said second type, a nominal value of said first current is a subtraction of a value of said second current from an ideal value of said first detection current, and said second current is greater than said third current.

4. The detection circuit of claim 3, wherein a ratio of said second current to said third current is a power of two.

5. The detection circuit of claim 1, wherein said first current source, said second current source, and said third current source are connected in parallel.

6. A detection circuit for power over Ethernet (PoE), disposed at power sourcing equipment (PSE), and operable to generate a first detection current in a first detection mode to conduct a detection of a power device (PD) of a first type and generate a second detection current in a second detection mode to conduct a detection of a PD of a second type, said detection circuit comprising:
a first current source group, comprising at least one first current source, for generating part of said first detection current in said first detection mode; and
a second current source group, comprising a plurality of second current sources, for generating part of said first detection current in said first detection mode and generating said second detection current in said second detection mode;
wherein, said first current source group does not generate current in said second detection mode.

7. The detection circuit of claim 6, wherein said first detection current is substantially a constant value in said first detection mode, and said second current sources generate different second detection currents in said second detection mode.

8. The detection circuit of claim 6, wherein said PSE comprises a first connection port and a second connection port for connecting different PDs, and said first connection port and said second connection port share said first current source group.

9. The detection circuit of claim 8 further comprising:
a third current source group, comprising a plurality of third current sources, for generating part of said first detection current in said first detection mode and generating said second detection current in said second detection mode;
wherein, in said second detection mode, said second current source group generates said second detection current at said first connection port and said third current source group generates said second detection current at said second connection port.

10. The detection circuit of claim 6, wherein the current values of said second current sources present a sequence of powers of two.

11. The detection circuit of claim 6, wherein said first current source group and said second current source group are connected in parallel.

12. A detection current generation method for power over Ethernet (PoE), applied to power sourcing equipment (PSE) of PoE, for generating a first detection current in a first detection mode to conduct a detection of a power device (PD) of a first type and generating a second detection current in a second detection mode to conduct a detection of a PD of a second type, said method comprising:
using a first current source group to generate part of said first detection current in said first detection mode, said first current source group comprising at least one first current source;
using a second current source group to generate part of said first detection current in said first detection mode, said second current source group comprising a plurality of second current sources;
controlling said first current source group not to generate current in said second detection mode; and
using said second current source group to generate said second detection current in said second detection mode.

13. The method of claim 12, wherein said first detection current is substantially a constant value in said first detection mode, and said second current source generates different second detection currents in said second detection mode.

14. The method of claim 12, wherein said PSE of PoE comprises a first connection port and a second connection port that connect different PDs, and said method further comprises:
using said first current source group to provide part of said first detection current at said first connection port and at said second connection port, one at a time, in said first detection mode.

15. The method of claim 14 further comprising:
using said second current source group to provide said second detection current at said first connection port in said second detection mode; and
using a third current source group to provide said second detection current at said second connection port in said second detection mode, said third current source group comprising a plurality of third current sources.

16. The method of claim 12, wherein the values of said second current sources present a sequence of powers of two.

17. The method of claim 12, wherein said first current source group and said second current source group are connected in parallel.
